(19) United States
(12) Patent Application Publication
(10) Pub. No.: US 2010/0018762 A1
(43) Pub. Date: Jan. 28, 2010

(54) BUILDUP PRINTED CIRCUIT BOARD

(75) Inventors: Hideaki YOSHIMURA, Kawasaki (JP); Norikazu OZAKI, Kawasaki (JP); Kenji IIDA, Kawasaki (JP); Tomoyuki ABE, Kawasaki (JP)

Correspondence Address: SQUIRE, SANDERS & DEMPSEY L.L.P., 8000 TOWERS CRESCENT DRIVE, 14TH FLOOR, VIENNA, VA, 22182-6212, US

(73) Assignee: FUJITSU LIMITED

(21) Appl. No.: 12/502,268

(22) Filed: Jul. 14, 2009

(30) Foreign Application Priority Data
Jul. 28, 2008 (JP) 2008-193386

(51) Int. Cl. H05K 1/11; H05K 3/36; B23P 23/00

(52) U.S. Cl. 174/262; 29/830; 29/33 R

(57) ABSTRACT

A printed circuit board includes a first insulation layer that is formed of a resin material into which fiber cloth is embedded. A second insulation layer is formed of a resin material, and is stacked on a front surface of the first insulation layer on which a heating process has been performed. A conductive land is formed on a front surface of the second insulation layer. A via is provided in a through hole penetrating through the first insulation layer and the second insulation layer. The through hole is filled with a conductive material, and the via is connected to the conductive land.

### CROSS-REFERENCE TO RELATED APPLICATION:

This application is based upon and claims the benefit of priority of the prior Japanese Patent Application No. 2008-193386, filed on Jul. 28, 2008, the entire contents of which are incorporated herein by reference.

### BACKGROUND

1. Field

The present invention relates to a buildup printed circuit board including an insulation layer.

2. Description of Related Art

A buildup printed circuit board is widely known as a printed circuit board (PCB) of multilayer structure. The buildup printed circuit board includes conductive wiring layers and resinous insulation layers which are stacked in sequence. Through holes are formed in the insulation layers. The through holes are filled with conductive material to create vias. Vias allow the electrical connection of the conductive wiring layers on opposite sides of the insulation layer. For example, silica as a filler of low thermal expansion is incorporated in the insulation layers such that the thermal expansion coefficient of the insulation layers is accommodated to that of the conductive wiring layers (see, for example, Japanese Laid-open Patent Publication No. 2005-268517).

A semiconductor chip, for example, is mounted on the front surface of the buildup printed circuit board with a solder bump. The solder bump is sandwiched between a conductive pad on the buildup printed circuit board and the corresponding conductive pad of the semiconductor chip. However, a sufficient rigidity is not ensured by the resinous insulation layer in which the filler such as silica is incorporated. Since the conductive wiring layer of copper and the insulation layer are stacked in sequence despite a different thermal expansion rate, the buildup printed circuit board may be deformed at a soldering temperature unless the rigidity of the insulation layer is sufficiently ensured. As a result, the solder joint between the buildup printed circuit board and the semiconductor chip may be poorly formed.

### SUMMARY

According to an aspect of the present invention, a buildup printed circuit board includes a first insulation layer that is formed of a resin material into which fiber cloth is embedded, and a second insulation layer that is formed of a resin material. The second insulation layer is stacked on a front surface of the first insulation layer on which a heating process has been performed. A conductive land is formed on a front surface of the second insulation layers, and a via which is provided in a through hole penetrates through the first insulation layer and the second insulation layer. The through hole is filled with a conductive material, and the via is connected to the conductive land.

It is to be understood that both the foregoing general description and the following detailed description are exemplary, and are not restricted to the invention, as claimed.

### BRIEF DESCRIPTION OF DRAWINGS

The above and other objects, features and advantages of the present invention will become apparent from the following description of the preferred embodiments in conjunction with the accompanying drawings, wherein:

FIG. 1 shows a sectional view of a buildup printed circuit board according to one embodiment of the present invention;

FIG. 2 shows an enlarged partial sectional view of the buildup printed circuit board;

FIG. 3 is a schematic view showing the step of stacking a conductive wiring layer on the rear surface of a first resin sheet;

FIG. 4 is a schematic view showing the step of stacking a second resin sheet on the front surface of the first resin sheet;

FIG. 5 is a schematic view showing the step of forming a through hole in the laminated resin sheets;

FIG. 6 is a schematic view showing the step of applying a photoresist on the front surface of the laminated resin sheets;

FIG. 7 is a schematic view showing the step of performing electrolytic plating on the front surface of the laminated resin sheets; and

FIG. 8 is a schematic view showing the step of removing the photoresist from the front surface of the laminated resin sheets.

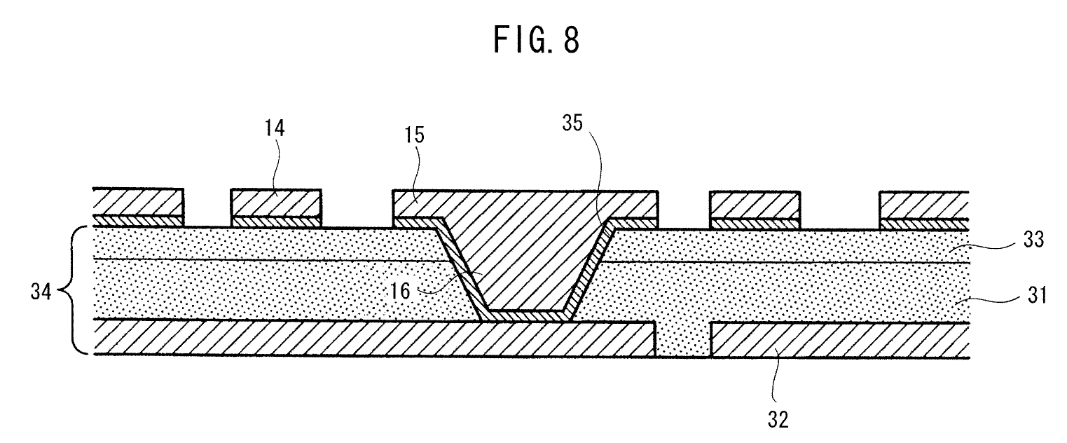

### DESCRIPTION OF EMBODIMENTS

Hereinafter, one embodiment of the present invention will be described with reference to the accompanying drawings.

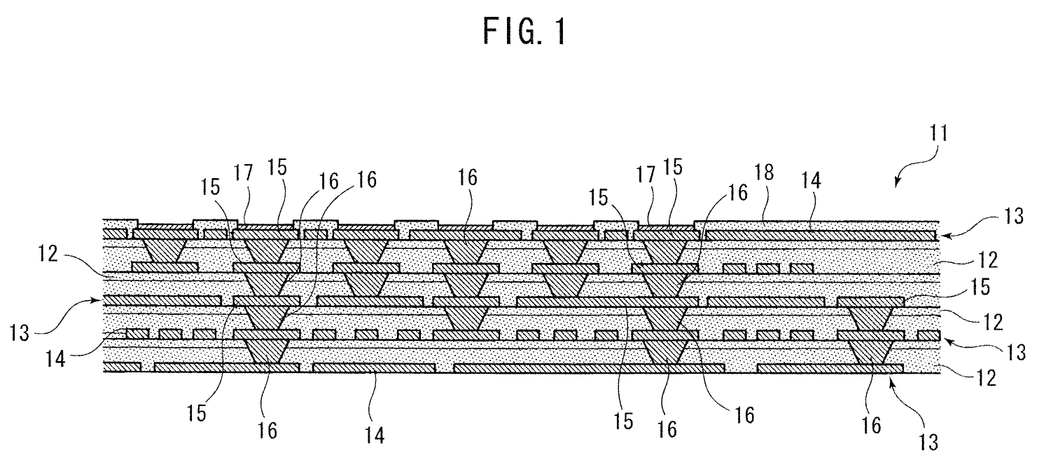

FIG. 1 shows a schematic sectional view of a buildup printed circuit board 11 according to one embodiment of the invention. The buildup printed circuit board 11 can be a laminated body that a plurality of insulation layers 12 and conductive wiring layers 13 is stacked in sequence. In the example of FIG. 1, four insulation layers 12 and five conductive wiring layers 13 are interlaminated. As mentioned later, a glass fiber cloth, for example, is embedded in the insulation layer 12. The glass fiber cloth may be a woven cloth or an unwoven cloth which is formed of glass fiber yarns. The insulation layer 12 according to the embodiment has sufficient rigidity to maintain a stand-alone shape. Instead of the glass fiber cloth, an aramid fiber cloth may be employed.

The conductive wiring layer 13 includes a conductive pattern 14 which extends on the insulation layer 12. Likewise, the conductive wiring layer 13 includes conductive lands 15 which can be formed on the front surface of the insulation layer 12. The conductive pattern 14 is connected to the conductive lands 15. The conductive lands 15 between which the insulation layer 12 is sandwiched are electrically connected by a via 16. In forming the via 16, a through hole is formed between the conductive lands 15 in the insulation layer 12. The through hole is filled up with a conductive material. The conductive wiring layer 13 and the via 16 can be formed from a conductive material such as Cu (copper).

A plurality of conductive pads 17 can be exposed to the front surface of the buildup printed circuit board 11. The conductive pad 17 is connected to the conductive land 15. The conductive pads 17 are formed with a conductive material, for example, Cu (copper). An overcoat layer 18 is stacked on the regions of the front surface of the buildup printed circuit board 11 except the conductive pads 17. A resin material, for example, is employed for the overcoat layer 18. The conductive pad 17 at the front surface of the buildup printed circuit board 11 is electrically connected to the conductive wiring layer 13 at the rear surface of this buildup printed circuit board 11.

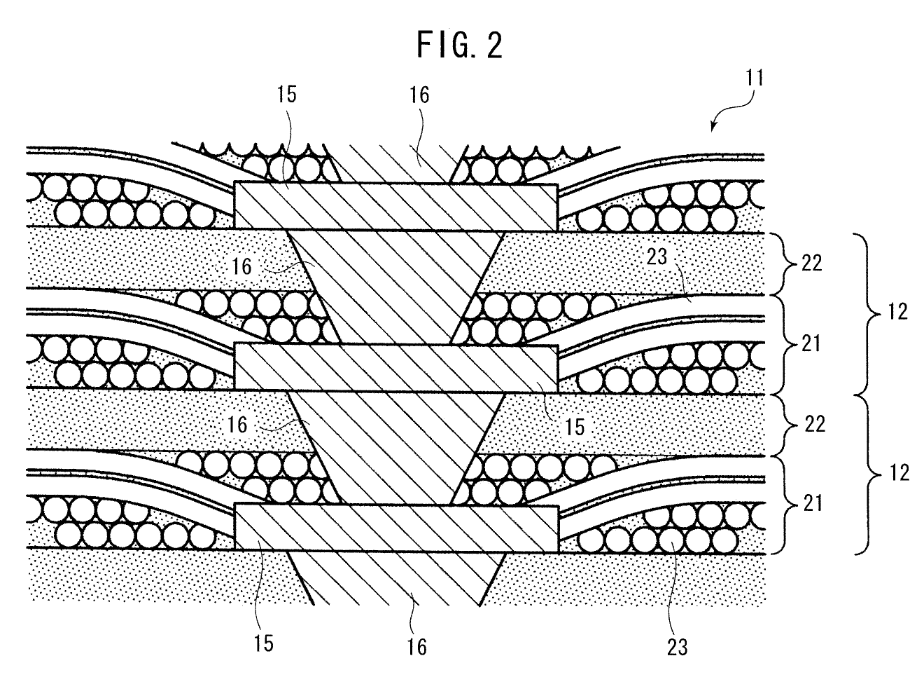

FIG. 2 shows an enlarged partial sectional view of the buildup printed circuit board. Each of the insulation layers 12 includes a first insulation layer 21, and a second insulation layer 22 which is stacked on the front surface of the first insulation layer 21. A glass fiber cloth 23 is embedded in the first insulation layer 21. In this embodiment, the glass fiber cloth 23 is formed from a woven cloth. The fibers of the glass fiber cloth 23 extend along the front surface and rear surface of the first insulation layer 21. In forming the first insulation layer 21, the glass fiber cloth 23 is impregnated with a resin material. The second insulation layer 22 does not contain any fiber therein, but it is formed with the resin material. A heat-curable resin, for example an epoxy resin, can be employed as the resin material. The thickness of the first insulation layer 21 is set to be greater than that of the second insulation layer 22. In the embodiment, the thickness of the first insulation layer 21 is set to 40 μm, for example. The thickness of the second insulation layer 22 is set to 10 μm, for example.

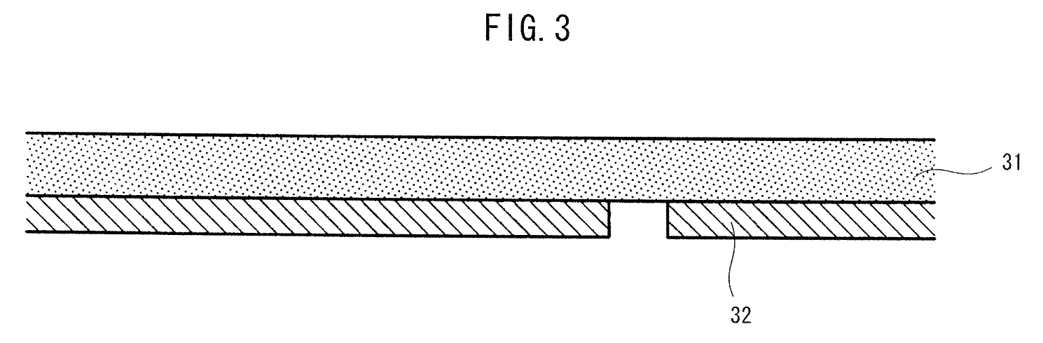

Next, a method for manufacturing the buildup printed circuit board 11 will be described. FIG. 3 is a schematic view showing the step of stacking a conductive wiring layer 32 on the rear surface of a first resin sheet 31. In the first resin sheet 31, a glass fiber cloth is embedded in a resin material. The fibers of the glass fiber cloth extend along the front surface and the rear surface of the first resin sheet 31. In forming the first resin sheet 31, the glass fiber cloth is impregnated with an epoxy resin. The conductive wiring layer 32 is stuck on the rear surface of the first resin sheet 31. A heating process is performed for the first resin sheet 31. At this time, the temperature of the heating process is set such that the epoxy resin is not completely hardened. As a result, the epoxy resin is semi-hardened in the first resin sheet 31. The shape of the first resin sheet 31 conforms to that of the conductive wiring layer 32. The first resin sheet 31 may be regarded as the first insulation layer 21. The conductive wiring layer 32 may be regarded as the conductive wiring layer 13.

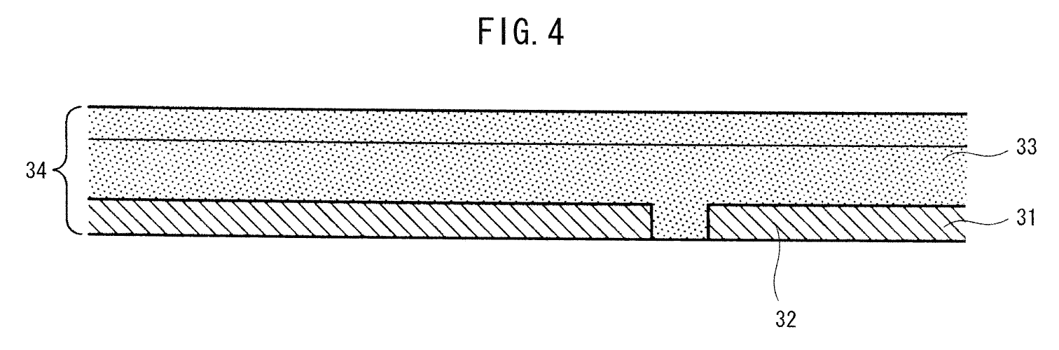

FIG. 4 is a schematic view showing the step of stacking a second resin sheet 33 on the front surface of the first resin sheet 31. The second resin sheet 33 is formed of an epoxy resin. Glass fiber cloth is typically not embedded in the second resin sheet 33. A heating process is performed in a state where the second resin sheet 33 is stacked on the front surface of the first resin sheet 31. The temperature of the heating process is set such that the epoxy resins of the first resin sheet 31 and the second resin sheet 33 are completely hardened. When the epoxy resins of the first resin sheet 31 and the second resin sheet 33 are completely hardened, the interface between the first resin sheet 31 and the second resin sheet 33 is held in close contact, and a laminated body 34 is formed because the epoxy resin in the first resin sheet 31 has been in a semi-hardened state due to the foregoing heating process. The first resin sheet 31 may be regarded as the second insulation layer 22. The laminated body 34 may be regarded as the insulation layer 12.

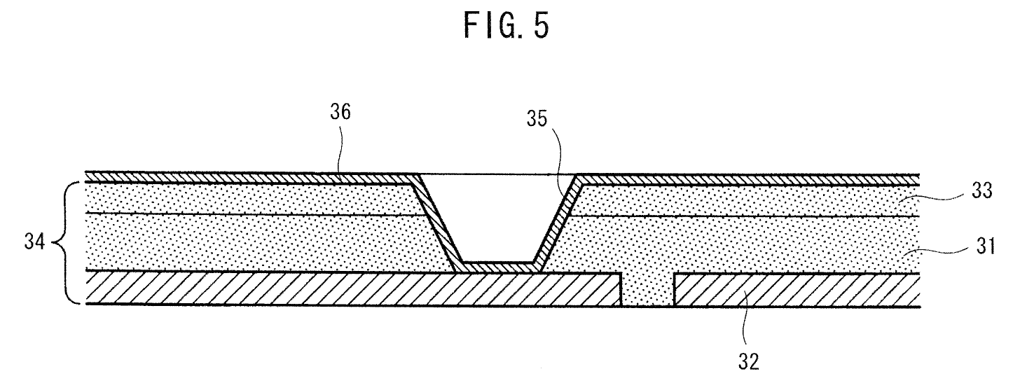

FIG. 5 is a schematic view showing the step of forming a through hole 35 in the laminated body 34 of the resin sheets. The laminated body 34 is provided with the through hole 35 at a predetermined position. The through hole 35 may be formed, for example, by a laser drill method. The through hole 35 penetrates through the first resin sheet 31 and the second resin sheet 33. The through hole 35 defines a space on the conductive wiring layer 32. After the formation of the through hole 35, a desmear process is performed on the front surface of the laminated body 34 so that smear in the through hole 35 is eliminated. In the desmear process, sodium permanganate or potassium permanganate may be employed. Incidentally, a roughening process unlevels the front surface of the first resin sheet 31 and the front surface of the second resin sheet 33. In the through hole 35, the glass fiber cloth of the first resin sheet 31 is exposed due to the melting of the resin material.

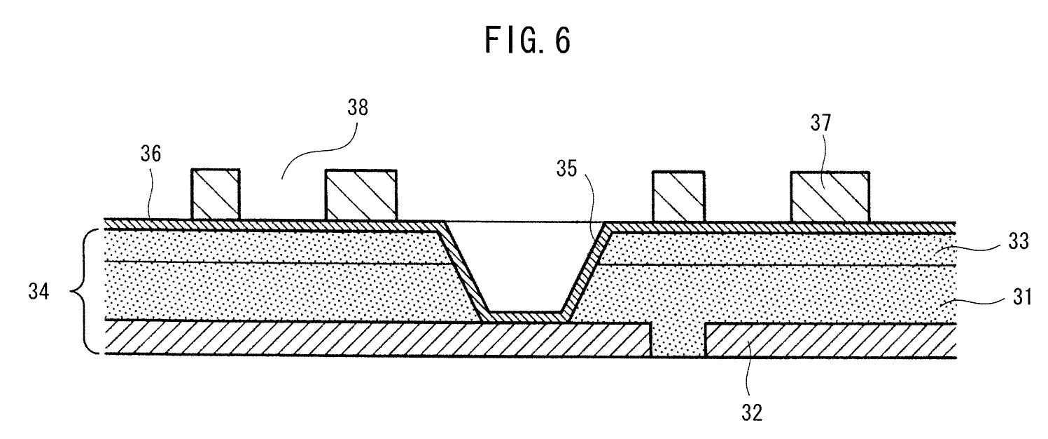

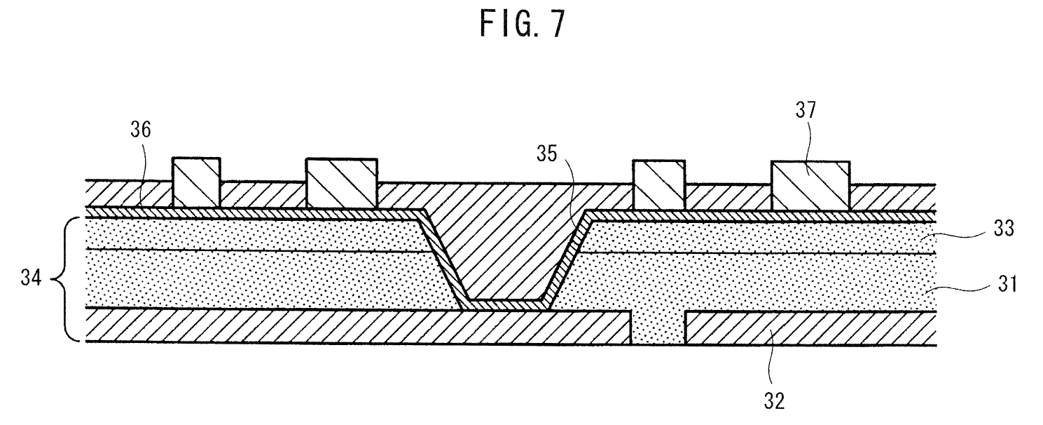

Then, an electroless deposition is performed on the front surface of the laminated body 34 to create a seed layer 36 of conductive material. The seed layer 36 extends into the through hole 35. Thereafter, as depicted in FIG. 6, a photoresist 37 with a predetermined pattern is formed on the seed layer 36. The photoresist 37 defines a void 38 in a predetermined pattern on the front surface of the laminated body 34. The through hole 35 is arranged within the void 38. As depicted in FIG. 7, an electrolytic plating of conductive material is performed on the front surface of the laminated body 34. Thereafter, the photoresist 37 is removed. After the removal of the photoresist 37, the exposed seed layer 36 within the removal regions of the photoresist 37 is also removed by etching on the front surface of the laminated body 34. In this way, the conductive pattern 14 is formed on the front surface of the laminated body 34. The via 16 is formed in the through hole 35. The conductive land 15 is formed on the through hole 35.

After the removal of the photoresist 37, another first resin sheet 31 is stacked on the front surface of the laminated body 34. The conductive wiring layer 13 is sandwiched in between the laminated body 34 and the first resin sheet 31. The first resin sheet 31 is subjected to a heating process, and it is further stuck on the front surface of the laminated body 34. As mentioned above, the shape of the first resin sheet 31 conforms to that of the conductive wiring layer 13. Thereafter, the stacking and heating process of the second resin sheet 33, the formation of the through hole 35, the electroless plating, the deposition of the photoresist 37, the electrolytic plating, and the removal of the photoresist 37 are similarly repeated. In this way, the insulation layers 12 and the conductive wiring layers 13 in prescribed numbers of stacked layers are formed. The uppermost layer of the laminated body 34 is provided with conductive pads 17 and the overcoat layer 18. In this way, the manufacture of the buildup printed circuit board 11 is completed.

According to an embodiment of the buildup printed circuit board 11, the glass fiber cloth 23 is embedded in the insulation layer 12. As a result, the thermal expansion coefficient of the insulation layer 12 is suppressed to be low. The thermal expansion coefficient of the insulation layer 12 is accommodated to that of the conductive wiring layer 13, whereby the occurrence of a stress within the buildup printed circuit board 11 may be suppressed. Moreover, the rigidity of the insulation layer 12 is heightened due to the glass fiber cloth 23. Thus, even when a device such as a semiconductor chip is mounted on the front surface of the buildup printed circuit board 11, the rigidity of the joint between the buildup printed circuit board 11 and the device may be reliably ensured.

As a comparative example, in a case where the glass fiber cloth 23 is adjacently embedded to the front surface of the insulation layer 12, the glass fiber cloth may be exposed with respect to the insulation layer 12. On this occasion, when a plating solution for the seed layer 36 flows into the through hole 35, the plating solution may soak into the insulation layer 12 along the interface between the resin material and the fibers of the glass fiber cloth. Due to this, the via 16 may be connected, through the plating solution, to the conductive wiring layer 13 which is formed on the front surface of the second resin sheet 33. As a result, the via 16 may be electrically connected to the conductive pattern 14, and an abnormality can occur in the conductive pattern. Such a buildup printed circuit board would be unusable.

According to the foregoing embodiment, the plating solution flows into the through hole 35 when the seed layer 36 is formed. When the glass fiber cloth is exposed into the through hole 35, the plating solution may also soak into the first resin sheet 31 along the interface between the resin material and the fibers of the glass fiber cloth. However, according to an embodiment of the buildup printed circuit board 11, the second resin sheet 33 can be stacked on the first resin sheet 31. As a result, the glass fiber cloth may be reliably prevented from being exposed from the front surface of the insulation layer 12, that is, the front surface of the second resin sheet 33. Accordingly, even if the plating solution soaks along the interface between the resin material and the fibers, the plating solution may be prevented from reaching the front surface of the second resin sheet 33. Consequently, the via 16 may be prevented from being electrically connected to the conductive pattern 14.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

We claim:

1. A printed circuit board, comprising:
a first insulation layer comprising a heat curable resin material having fiber cloth embedded therein;
a second insulation layer comprising a resin material, said second insulation layer being stacked on a front surface of the first insulation layer and subjected to a heating process;
a conductive land disposed on a front surface of the second insulation layer; and
a via, comprising a through hole penetrating through the first insulation layer and the second insulation layer, the through hole being filled with a conductive material, the via being connected to the conductive land.

2. A printed circuit board according to claim 1, wherein the second insulation layer has no fiber cloth embedded therein.

3. A printed circuit board according to claim 1, wherein:
the resin material of the first insulation layer comprises a heat-curable resin material; and
the heating process is performed until the heat-curable resin material of the first insulation layer reaches a semi-hardened state.

4. A printed circuit board according to claim 1, wherein the fiber cloth comprising at least one of a glass fiber and an aramid fiber.

5. A printed circuit board according to claim 1, wherein the fibers comprise one of a woven cloth and an unwoven cloth.

6. A method of manufacturing a printed circuit board comprising:
embedding a fiber cloth into a resin material to form a first insulation layer;
performing a first heating process on the first insulation layer;
stacking a second insulation layer of a resin material onto a front surface of the first insulation layer on which the first heating process has been performed;
performing a second heating process on the first insulation layer and the second insulation layer;
forming a through hole which penetrates through the second insulation layer and the first insulation layer;
filling a conductive material into the through hole to form a via; and
forming a conductive land on a front surface of the second insulation layer to connect the conductive land to the via.

7. A method of manufacturing a printed circuit board according to claim 6, wherein:
the resin material of the first insulation layer is a heat-curable resin material; and
the first heating process is performed until the heat-curable resin material of the first insulation layer reaches a semi-hardened state.

8. A system for manufacturing a printed circuit board, said system comprising:
embedding means for embedding a fiber cloth into a resin material to form a first insulation layer;
first performing means for performing a first heating process on the first insulation layer;
stacking means for stacking a second insulation layer of a resin material onto a front surface of the first insulation layer on which the first heating process has been performed;
second performing means for performing a second heating process on the first insulation layer and the second insulation layer;
first forming means for forming a through hole which penetrates through the second insulation layer and the first insulation layer;
filling means for filling a conductive material into the through hole to form a via; and
second forming means for forming a conductive land on a front surface of the second insulation layer to connect the conductive land to the via.

9. A system according to claim 8, wherein said first performing means performs the first heating process until the first insulation layer reaches a semi-hardened state.

10. A system for manufacturing a print circuit board, said system comprising:
an embedding unit configured to embed a fiber cloth into a resin material to form a first insulation layer;
a first performing unit configured to perform a first heating process on the first insulation layer;
a stacking unit configured to stack a second insulation layer of a resin material onto a front surface of the first insulation layer on which the first heating process has been performed;
a second performing unit configured to perform a second heating process on the first insulation layer and the second insulation layer;
a first forming unit configured to form a through hole which penetrates through the second insulation layer and the first insulation layer;
a filling unit configured to fill a conductive material onto the through hole to form a via; and
a second forming unit for forming a conductive land on a front surface of the second insulation layer to connect the conductive land to the via.

11. A printed circuit board, comprising:
first insulation means for insulating between conductive layers, said first insulation means comprising heat curable resin material having fiber cloth embedded therein;
second insulation means for insulating between conductive layers, said second insulation means comprising a resin material, said second insulation means being stacked on a front surface of the first insulation means and being subjected to a heating process;
conductive means for conducting electricity, said conductive means disposed on a front surface of the second insulation means; and
via means for conducting between conductive layers, said via means comprising a through hole penetrating through the first insulation means and the second insulation means, the through hole being filled with a conductive material, with the via being connected to the conductive means.
